(19) United States
(12) Patent Application Publication
(10) Pub. No.: US 2006/0185727 A1
(43) Pub. Date: Aug. 24, 2006

(54) Converter circuit and technique for increasing the output efficiency of a variable power source

(75) Inventor: Stefan Matan, Novato, CA (US)

Correspondence Address: PAUL, HASTINGS, JANOFSKY & WALKER LLP, P.O. BOX 919092, SAN DIEGO, CA, 92191-9092, US

(73) Assignee: ISG Technologies LLC, Los Gatos, CA (US)

(21) Appl. No.: 11/291,110

(22) Filed: Nov. 29, 2005

Related U.S. Application Data
(60) Provisional application No. 60/640,071, filed on Dec. 29, 2004.
(60) Provisional application No. 60/640,083, filed on Dec. 29, 2004.

(51) Int. Cl. H01L 31/042

(52) U.S. Cl. 136/293; 136/244

(57) ABSTRACT

The present invention provides a converter circuit and accompanying switch mode power conversion technique to efficiently capture the power generated from a solar cell array that would normally have been lost, for example, under reduced incident solar radiation. In an embodiment of the invention, the converter circuit generates an output current from the solar cell power source using a switch mode power converter. A control loop is closed around the input voltage to the converter circuit and not around the output voltage. The output voltage is allowed to float, being clamped by the loading conditions. If the outputs from multiple units are tied together, the currents will sum. If the output(s) are connected to a battery, the battery's potential will clamp the voltage during charge. This technique allows all solar cells in an array that are producing power and connected in parallel to work at their peak efficiency.

### CROSS-REFERENCE TO RELATED APPLICATION

The present invention claims priority under 35 U.S.C. § 119(e) to U.S. Provisional Patent Application No. 60/640,083, entitled “Increase Photovoltaic Power Conversion by Converter Circuit,” and filed on Nov. 29, 2004, the disclosure of which is hereby incorporated by reference in its entirety.

### BACKGROUND OF INVENTION

1. Field of Invention

The present invention relates generally to electrical power systems and more particularly, to a converter circuit for increasing the output power efficiency of a variable power source, such as a solar cell.

2. Description of Related Art

Solar power is a clean and renewable source of energy that has mass market appeal. Among its many uses, solar power can be used to convert the energy from the sun either directly or indirectly into electricity. The photovoltaic cell is a device for converting sunlight energy directly into electricity. When photovoltaic cells are used in this manner they are typically referred to as solar cells. A solar cell array or module is simply a group of solar cells electrically connected and packaged together. One of the drawbacks of the utilization of solar cells are their relatively expensiveness due to the high cost of production and low energy efficiency, e.g., 3 to 28 percent.

Prior techniques have been employed to improve the efficiency of solar cells. One of the earliest improvements was the addition of a battery to a solar cell circuit to load level the electrical output from the circuit during times of increased or decreased solar intensity. In itself, a photovoltaic or solar array can supply electrical power directly to an electrical load. However, the major drawback of such a configuration is the diurnal variance of the solar intensity. For instance, during daylight operation, a solar cell produces excess power while during nighttime or periods of reduced sunlight there is little or no power supplied from the solar cell. In the simplest electrical load leveling scenario, the battery is charged by the solar cell during periods of excessive solar radiation, e.g., daylight, and the energy stored in the battery is then used to supply electrical power during nighttime periods.

A single solar cell normally produces a voltage and current much less than the typical requirement of an electrical load. For instance, a typical conventional solar cell provides between 0.2 and 1.4 Volts of electrical potential and 0.1 to 5 Amperes of current, depending on the type of solar cell and the ambient conditions under which it is operating, e.g., direct sunlight, cloudy/rainy conditions, etc. An electrical load typically requires anywhere between 5-48 V and 0.1-20 A. To overcome this mismatch of electrical source to load, a number of solar cells are arranged in series to provide the needed voltage requirement, and arranged in parallel to provide the needed current requirement. These arrangements are susceptible since if there is a weak or damaged cell in the solar cell array, the voltage or current will drop and the array will not function to specification. For example, it is normal to configure a solar cell array for a higher voltage of 17 V to provide the necessary 12 V to a battery. The additional 5 V provides a safety margin for the variation in solar cell manufacturing and/or solar cell operation, e.g., reduced sun light conditions.

Since the current produced by solar cell arrays is constant, in the best of lighting conditions, the solar cell array loses efficiency due to the fixed voltage of the battery. For example, a solar cell array rated for 75 Watts at 17 Volts will have a maximum current of 75/17=4.41 Amperes. During direct sunlight, the solar cell array will in reality produce 17 V and 4.41 A, but since the battery is rated at 12V, the power transferred will only be 12*4.41=52.94 Watts, for a power loss of about 30%. This is a significant power loss; however, it is not desirable to reduce the maximum possible voltage provided by the solar cell array because under reduced sunlight conditions, the current and voltage produced by the solar cell array will drop due to low electron generation, and thus might not able to charge the battery.

FIGS. 1(a)-(d) illustrate Current-Voltage (I-V) and power behavior outputs of a conventional solar cell module under different sunlight intensities and conditions. The current in milliamperes (mA) is plotted on the vertical y axis (ordinate) and the voltage in volts (V) is plotted on the horizontal x axis (abscissa). These figures show the shortcomings of the prior art in providing electrical load leveling for a typical 12 V battery connected to a solar cell array for energy storage during the daylight hours of sunlight whether full sun or not.

Six different I-V curves are shown in FIG. 1(a). Three of the curves are for a crystalline solar cell and another three of the curves are for an amorphous silicon module (ASM) solar cell array. The solar intensity falling on the arrays are labeled as 10, 100, and 200 Watts (W) per square-meter (W/m²). The “Battery Charging Window” is illustrated by the two parallel slightly curved lines moving up from 11 and 14 volts on the x axis.

Also illustrated in this figure is the case where the lowest intensity I-V curves at 10 W/m² enter slightly or not at all the “Battery Charging Window,” thereby resulting in little or no charging of the battery. This would be the case for heavily clouded or rainy days. Also shown is the result that some of the charging of the battery takes place to a lesser degree from the moderate intensity at 100 W/m² depending on the type of solar cell array. This would be the case for semi-cloudy days. Finally, the condition for a high intensity flooding of the solar cell array at 200 W/m² is shown. This would be the case for full sun days. In effect, FIG. 1(a) shows that the charging of a battery directly from the solar cell arrays may not yield an optimum result depending on the type of solar cell array used and the conditions of the solar environment to which the solar cell array is exposed.

Industry standard crystalline solar cells are only effective at charging a 12 V battery at the highest intensity of 200 W/m². Also, the ASM, which is one of the most efficient present day solar cell arrays, although providing more charging power to the battery at all but the lowest of intensities, still indicates a significant fall off in power due to a decrease in current from the highest to the lowest solar intensity. So even for the most efficient solar cell modules available today, optimum power is still not being delivered to the battery.

A Maximum Power Point Tracking (MPPT or “power tracker”) is an electronic DC to DC converter that optimizes the match between the solar cell array and the battery. A MPPT can recover some of the power loss, provided that the power consumed by the MPPT circuitry is not excessive. In the example of the solar cell array outputting 75 W at 25 V (3 A maximum) described above, the addition of a MPPT circuit reduces the voltage output of the solar cell array to 13 V. Assuming the power consumed by the MPPT is minimal, the DC to DC converter conserves the 75 W of output power, and thus the output of the DC to DC converter is 13 V, 5.77 A (from conservation of power 25 V×3 A=13 V×5.77 A). Accordingly, the current produced is higher with the MPPT than the maximum current of the solar cell array without the MPPT. The reason for the use of 13 V is to provide a positive one Volt difference between the output of the MPPT circuit and the battery. However, a MPPT circuit requires a minimum voltage and power to operate. For instance, the minimum input requirements of a typical MPPT circuit available on the market is 19 volts at 50 watts of power. Other MPPT circuits require higher input voltages and powers. Thus if the voltage drops below 19 volts, for example, the MPPT circuit does not operate. Moreover, MPPT circuits are relatively expensive.

The challenge with using solar cell devices is that the power generated by these devices varies significantly based on both the exposure to sunlight and the electrical load applied to the device. A maximum current can be achieved with a short circuited load, but under this condition, the output power generated by the solar cell device is zero. On the other hand, if the load has a maximum voltage, the current derived from the solar cell device drops to zero, and then again no power is generated. Therefore, in order to yield maximum power the output load has to be adjusted based on the exposure level of the solar cell array to sunlight.

The sunlight conditions are often controlling on the performance of a solar cell array. A few notable conditions are illustrated in FIGS. 1(b)-(d).

FIG. 1(b) shows the electrical behavior of a 12 W flexible solar panel array under the conditions of low sunlight exposure levels due to an early morning indirect sun or an open sun at high angles of incidence to the array. Designated by the left vertical axis is the solar array output power in milliwatts and designated on the right vertical axis is the solar array output current in millamperes. The voltage output of the solar array is designated on the horizontal axis. As illustrated by the data plotted, the power and current outputs for this particular solar cell array cannot generate power to charge a 12V battery within the boundaries of the given lighting conditions. Power is available in excess of 10% of array capacity, but in order to make use of this power, a 12V battery cannot be used as in this example.

FIG. 1(c) shows the electrical behavior for the same 12 W flexible solar panel, but, in this case, under the conditions of increased sunlight illumination, but not full sunlight. It can be readily seen from this figure that the maximum power that may be obtained under these conditions is 8.65 W at 9.5 V, but it is commonly known that 13.5 V is necessary to charge a 12 V battery. At the required 12 V, the power available drops to 6 W, a reduction of 31% in the available power.

FIG. 1(d) shows the electrical behavior for the same flexible solar panel under exposure to full sun. In this case, the maximum output is 5.177 W at 16 V. However, the power available at 12 V is only 4.4 W. This is a reduction of 18% of the available power. The maximum voltage available is 16 V even though this flexible solar panel was originally designed for operation at 12 V.

With the exclusion of the highest sunlight intensities, the above examples show the deficiency of the prior art in matching the charging power requirements for a conventional 12 V battery. Accordingly, there is a need to efficiently capture the power of a solar cell during low power output due to, for example, reduced sunlight conditions.

### SUMMARY OF THE INVENTION

The present invention overcomes these and other deficiencies of the prior art by providing a converter circuit and accompanying switch mode power conversion technique to efficiently capture the power generated from a solar cell array that would normally have been lost, for example, under reduced incident solar radiation.

Under reduced incident solar radiation, a solar cell array does not receive enough sunlight to produce adequate power to charge an energy storage battery or to power a typical electrical load. Utilizing the switch mode power conversion technique of the present invention, input power to a converter circuit is equal to the output power generated by the converter circuit assuming no loses within the conversion process. As an example, 6 volts at 1 amp is converted to 12 volts at 0.5 amps. By utilizing switching topology, power is drawn from a photovoltaic device over a wider range of lighting conditions. A solar cell panel, which is designed to charge a 12 V battery, that is only generating 6 V due to subdued lighting, still generates a considerable amount of energy. Though the amount of power generated may be small, it is infinitely more than none. But, with the converter circuit of the present invention, given enough time, even in low-light conditions, the battery will reach full charge.

In an embodiment of the invention, a system comprises: a power source having a varying output voltage, and a converter circuit electrically coupled to the power source, wherein the converter circuit regulates the varying output voltage to a constant voltage. The converter circuit dynamically modifies an electrical load based on the available power generated by the power source. The power source may comprise one or more solar cells. The power source and the converter circuit may be enclosed by a single housing. The system may further comprise a battery electrically coupled to the converter circuit. The converter circuit charges the battery when the varying output voltage of the power source is below a charging voltage of the battery. The converter circuit may comprise a switch mode converter. The converter circuit may comprises: a primary coil of a transformer; a secondary coil of a transformer; a switch coupled to the primary coil; a pulse generator coupled to the switch, wherein the pulse generator controls the switch; a diode coupled to the secondary coil, and a capacitor coupled to the diode. The pulse generator may comprise a timer chip. The system may be implemented in numerous applications such as, but not limited to a universal battery charger, a laptop computer, a power generator, a cell phone charger, and a tent power generator.

An advantage of the present invention is that it dynamically modifies an electrical load based on the available power generated by a solar cell device, thereby achieving an operational point defined as the Maximum Possible Power Generated (MPPG). Another advantage of the present invention is that it will not overcharge a battery.

Other features and advantages of the invention will be apparent as described in the detailed embodiment section, figures and claims shown below.

### BRIEF DESCRIPTION OF THE DRAWINGS

For a more complete understanding of the present invention, the objects and advantages thereof, reference is now made to the following descriptions taken in connection with the accompanying drawings in which:

FIG. 1 illustrates Current-Voltage (I-V) and power behavior outputs of a conventional solar cell module charging a 12 volt battery under different sunlight intensities and conditions;

FIG. 2 illustrates a conventional solar cell array power supply system;

FIG. 3 illustrates a solar cell system according to an embodiment of the invention;

FIG. 4 illustrates a prior art voltage booster;

FIG. 5 illustrates a transformer flyback converter circuit according to an embodiment of the invention;

FIG. 6 illustrates a converter circuit according to another embodiment of the invention;

FIG. 7 illustrates a pulse width modulator according to an embodiment of the invention;

FIG. 8 illustrates a pulse generator within the converter circuit of FIG. 5 or 6;

FIG. 9 illustrates a circuit to enact stable operation according to an embodiment of the invention;

FIG. 10 illustrates an converter circuit using a 555 timer circuit according to an embodiment of the invention;

FIG. 11 illustrates multiple cascading converter circuits according to an embodiment of the invention;

FIG. 12 shows an application for the present invention for an universal battery charger;

FIG. 13 shows an application for the present invention for a laptop computer charger;

FIG. 14 shows an application for the present invention for a rolling backpack power generator and charger;

FIG. 15 shows an application for the present invention for a poncho power generator and charger;

FIG. 16 shows an application for the present invention for a tent power generator and charger; and

FIG. 17 shows an application for the present invention for a purse power generator and charger.

### DETAILED DESCRIPTION OF THE EMBODIMENTS

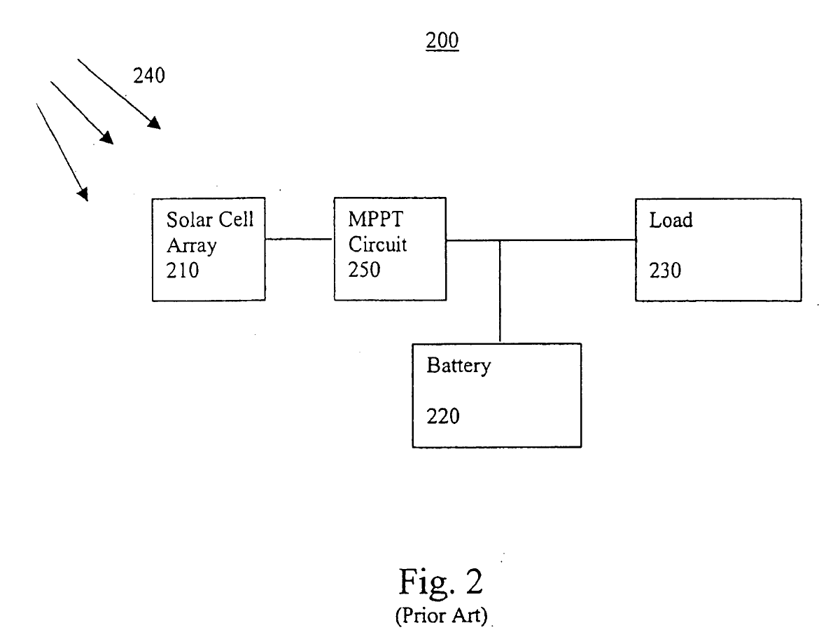

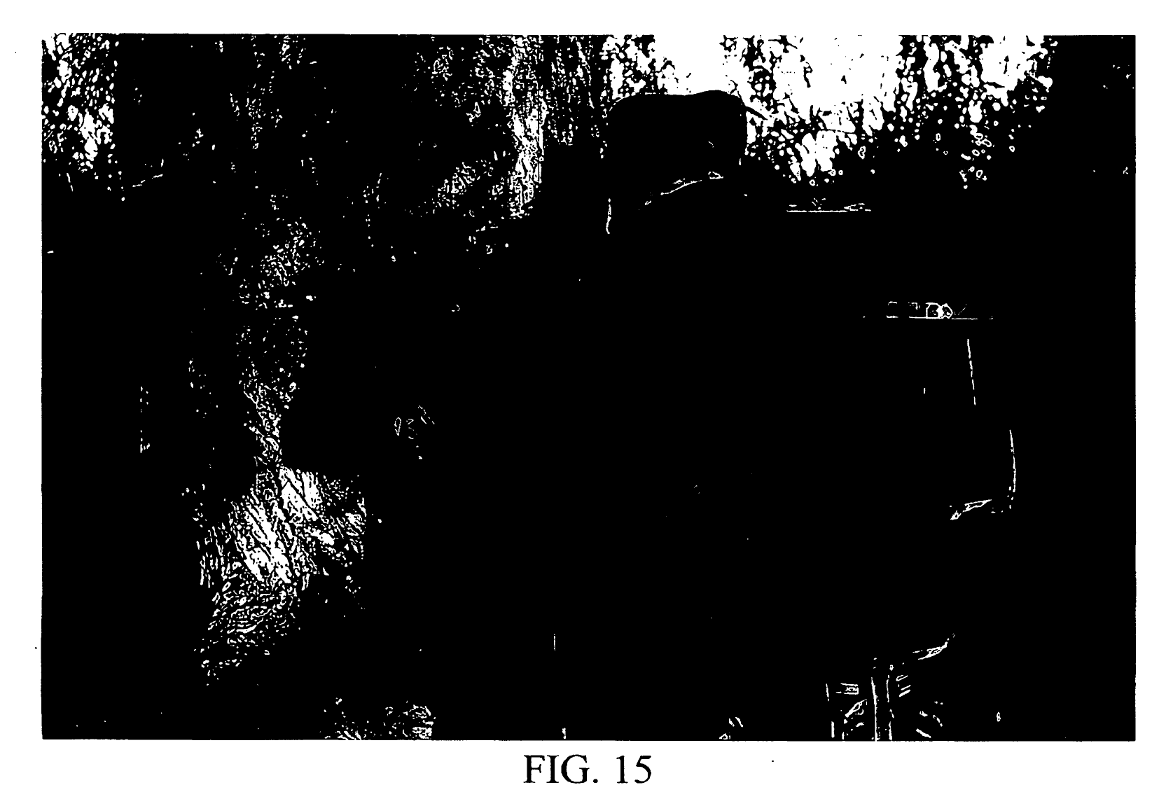

Further features and advantages of the invention, as well as the structure and operation of various embodiments of the invention, are described in detail below with reference to the accompanying FIGS. 2-17, wherein like reference numerals refer to like elements. The embodiments of the invention are described in the context of solar power and solar cells. Nonetheless, one of ordinary skill in the art readily recognizes that any photovoltaic device is encompassed by the embodiments of this invention as are other variable electrical power sources such as, but not limited to wind, geothermal, biomass, fuel cells and hydroelectric power sources.

Solar cell arrays are an excellent source of power since they can be operated anywhere under sunlight. However, improving the efficiency of the solar cell array is a major concern since solar cell arrays do not normally operate well under low light conditions. Specifically, since almost all solar cell arrays come with a rechargeable energy storage battery, the weather conditions that do not allow the solar cell array to produce adequate power to charge the battery render the array deficient.

FIG. 2 illustrates a conventional solar cell array power supply system 200. In this configuration, the solar cell array power supply system 200 comprises a solar cell array 210, a battery 220, an electrical load 230, and a MPPT circuit 250. The battery 220 and the load 230 are designed for operation at a predetermined voltage, for example, 12 V, and do not operate at any lower voltage. Solar energy 240 is converted to electrical energy at the solar cell array 210. The solar cell array 210 is rated at a predetermined voltage, for example, 25 Volts, under direct full sunlight, so even under optimum sunlight illumination the configuration necessitates the MPPT circuit 250 for best efficiency. However, when the sunlight illumination 240 decreases, for example, under cloudy and/or rainy weather conditions, the solar cell array 210 produces voltages of less than 12 volts. Under such a scenario, the solar cell array 210 becomes inoperative even with the presence of the MPPT circuit 250 (e.g., the minimum input requirements of a typical MPPT circuit is 19 volts and 50 watts), and the power to the load 230 comes only from the battery 220 and not the solar cell array 210. This means that the power generated by the solar cell array 210 between 0 V and 12 V is wasted and the battery 220 voltage eventually discharges to an ineffective level for driving the load 230 before adequate sunlight illumination returned to the solar cell array 210.

The present invention improves the efficiency of a solar cell array without relying on the implementation of a costly MPPT circuit. The present invention is ideally suitable for low efficiency solar cells and flexible solar cells, and all solar cells or arrays operating under reduced sunlight conditions.

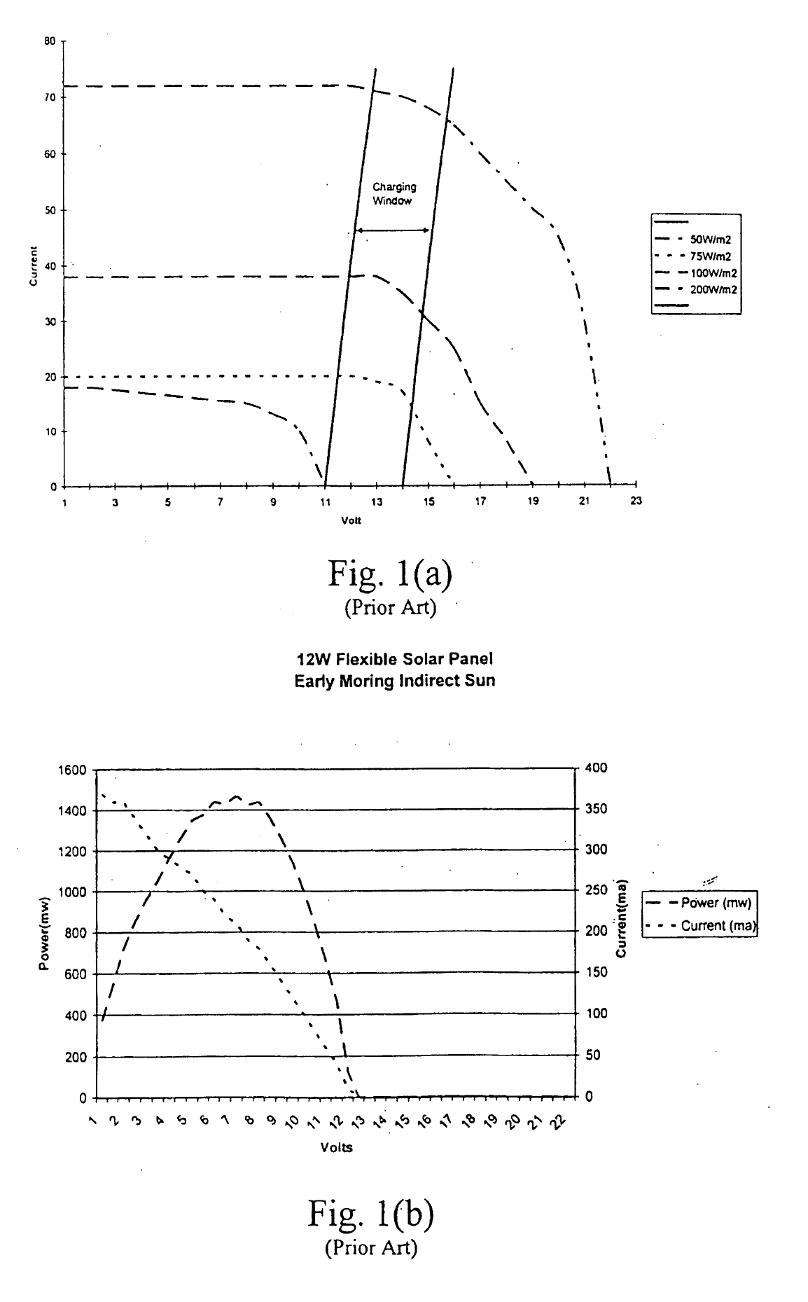

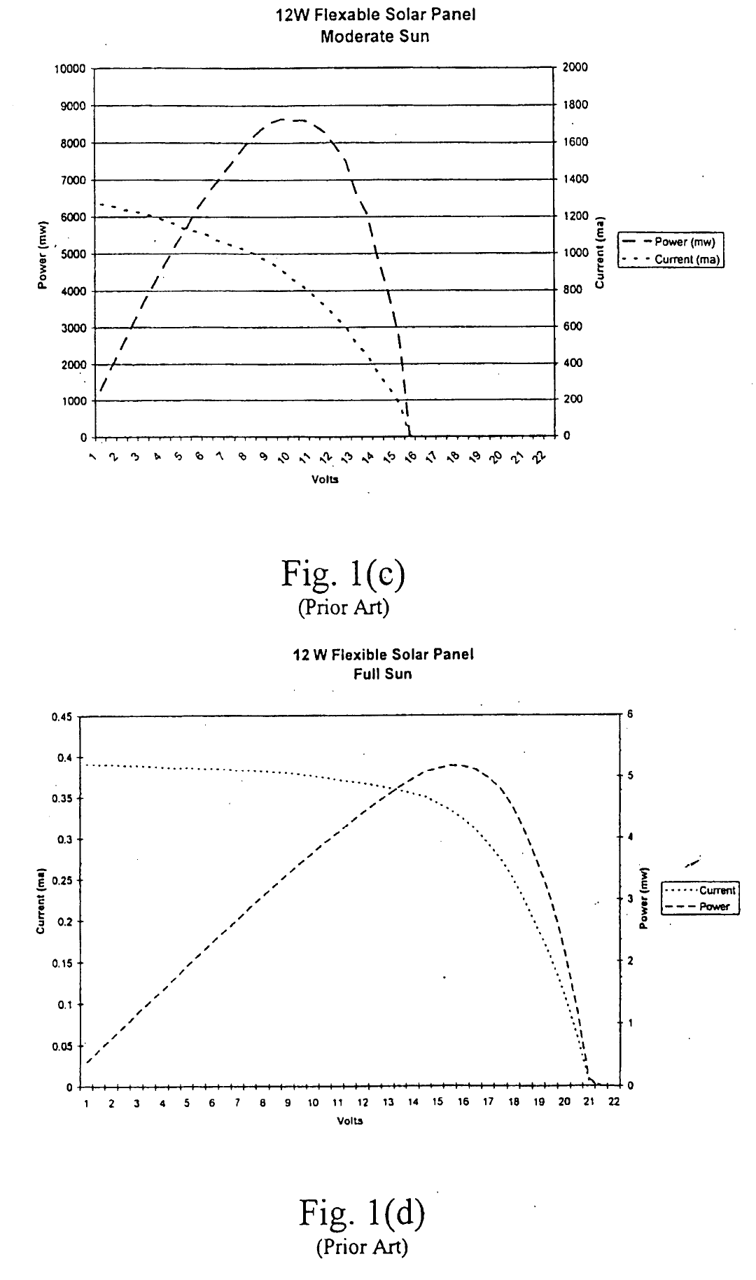

In an embodiment of the invention, the present invention comprises a DC to DC converter circuit that changes the voltage or current output of the solar cells before delivery to a load or battery. When a solar panel is connected directly to a battery or a load, the I-V characteristics of the solar panel give a constant current for a wide range of output voltage, up to a certain voltage. See, e.g., FIG. 1(a). Thus, if a 9 V, 1 A (9 W) solar panel is used to charge a 3 V battery, the charging current is still 1 A. When charging a 6 V battery, however, the solar panel still provides a 1 A current. By adding the DC to DC converter circuit (as will be shown and described in greater detail), the power characteristics of the solar panel changes. For example, by placing a 9 V to 18 V voltage step-up DC to DC converter between the solar panel and the battery, the charging current to the battery is different than the previous example since the DC to DC converter preserves the power. The power of the solar panel is 9 W, which is inputted to the DC to DC converter. Thus, the DC to DC converter delivers 9 W to the battery, assuming negligible power loss due to the DC to DC converter. Thus, the current charging a 3 V battery will be 3 A (=9 W/3V), a threefold increase compared to the circuit without the present invention. The same characteristics can be achieved with a voltage step-down DC to DC converter or a current step-up DC to DC converter, or a combination thereof. The present invention performs energy transfer by transforming the current derived from the solar cell or array.

The converter circuit of the present invention is unique as it closes the control loop around the input voltage to the converter circuit rather than the output voltage. The output current will vary such that the voltage output is regulated, i.e., held relatively constant.

In an embodiment of the invention, the output voltage of a switch mode power converter circuit is allowed to float, being clamped by the loading conditions. If the outputs from multiple solar cells with the converters are tied together, the currents sum together. If the outputs are connected to a battery, the battery's potential will clamp the voltage during charge. This methodology allows all cells that are producing power and connected in parallel to work at their peak efficiency. The present invention can perform better than a step-down MPPT circuit during reduced sunlight conditions where the solar output voltage is below the requirement of the MPPT circuit.

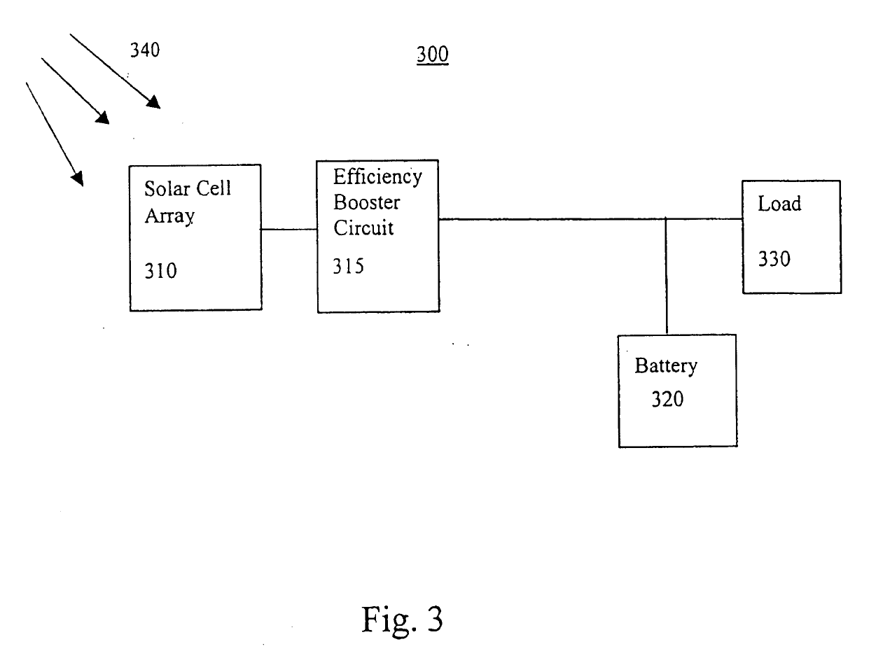

FIG. 3 illustrates a converter circuit system 300 according to an embodiment of the invention. The converter circuit system 300 comprises the solar cell array 210, a converter circuit 315, a battery 220, and an electrical load 230. The converter circuit 315 is disposed between the solar cell array 210 and the battery 220 and/or the load 230. The converter circuit 315 takes minimal power from the solar cell array 210 to operate its internal circuitry, thereby requiring no power external to the circuit. The converter circuit 315 comprises a voltage or current booster or buck (not shown), and is designed to change (increase or decrease) the voltage or current of the solar cell array 210. For example, suppose that the solar illumination 240 is partially obscured by clouds and solar cell array 210 only produces 5 V output for a 12 V battery 220. Without the converter circuit 315, the solar cell array 210 is unable to charge the battery 220 or operate the load 230, which requires voltages higher than 5 V. A prior art step-down MPPT circuit is unable to help in this situation since it only decreases voltage. The converter circuit 315 increases the voltage to a voltage high enough to charge the battery 220.

In an embodiment of the invention, the converter circuit 315 preferably changes the voltage in the range of 0.1× to 10×, and the booster voltage range can be from 0.5 V to 20 V difference, depending on the type of applications. The current variations are also similar, from 0.1× to 10× at magnitudes of 10 mA to 100 A.

A characteristic of the converter circuit 315 is its power requirement. Even though the converter circuit 315 is connected to the solar cell array 210 and the battery 220 and the load 230 with all of these components rated at high voltages (12-17 V in the above example), the converter circuit 315 is designed to operate at a much lower voltage (4-5 V or even lower, say 2.5 V). The reason for this is that the converter circuit 315 really only functions when the output voltage level of the solar cell array 210 is low and not when the solar cell array 210 is at its peak voltage. However, the converter circuit 315 also needs to sustain the high voltage of the solar cell array 210 at its peak. Therefore, in order for the solar cell array 210, which is rated at 17 V, to capture the power in the range of 4.5 V to 12 V, the converter circuit 315 is designed to operate in the range of 4.5 to 18 V.

In an embodiment of the invention, the converter circuit 315 comprises an optional circuit breaker (not shown), the implementation of which is apparent to one of ordinary skill in the art, to prevent damage to the converter circuit 315 at high power. For example, the above converter circuit 315 operates in the range of 4.5 to 12 V with a circuit breaker to disconnect and bypass the converter circuit 315 and directly connect the solar cell array 210 to the load or battery.

In another embodiment of the invention, the converter circuit 315 comprises an optional clamping circuit (not shown), the implementation of which is apparent to one of ordinary skill in the art, so that the voltage output of the converter circuit 315 is fixed at a predetermined value. If the input voltage from the solar cell array 210 is lower than the above fixed value, then the converter circuit 315 increases the voltage to the set fixed level. If the output voltage from the solar cell array 210 is higher than this value, then the converter circuit 315 provides a bypass route or simply clamps it down.

In yet another embodiment of the invention, multiple converter circuits 315 are cascaded together to further extract a wider range of power from the solar cell array 210. For example, a first converter circuit 315, which is operated in the range of 0.3 to 4.5 V, is cascaded with a second converter circuit 315, which is operated in the range of 4.5 to 17 V. Cascading of multiple converter circuits increases the overall power efficiency. None of the multiple converter circuits requires power external to the overall circuit. In this way, any electrical potential in the range of 0.3 to 17 volts can be extracted from a 17 V solar cell array 210 connecting to a 12 V battery 220.

The above discussion focuses on a solar cell array power extraction technique, however it is readily apparent to one of ordinary skill in the art that the converter circuit 315 can be applied to any electrical power supply, particularly a power supply, particularly a power supply with an electrical output that varies as a function of time. For example, in a hydroelectric power plant using flowing water to generate electricity through a turbine there are periods of reduced water flow that are not enough to match the existing electrical load. The converter circuit 315 extracts and thereby, stores the hydroelectric power that otherwise would be lost. Yet another application is wind power which uses air flow to generate electricity. During the periods of low winds that are insufficient to charge the existing electrical load the converter circuit 315 extracts and thereby, stores the wind power that otherwise might be lost.

In an embodiment of the invention, the converter circuit 315 is coupled to the voltage output of one or more fuel cells. During sleeping mode periods, a fuel cell generates some, but too little power for the existing electrical load. The converter circuit 315 extracts the power generated from fuel cells during the low power periods, which can then be stored in a battery.

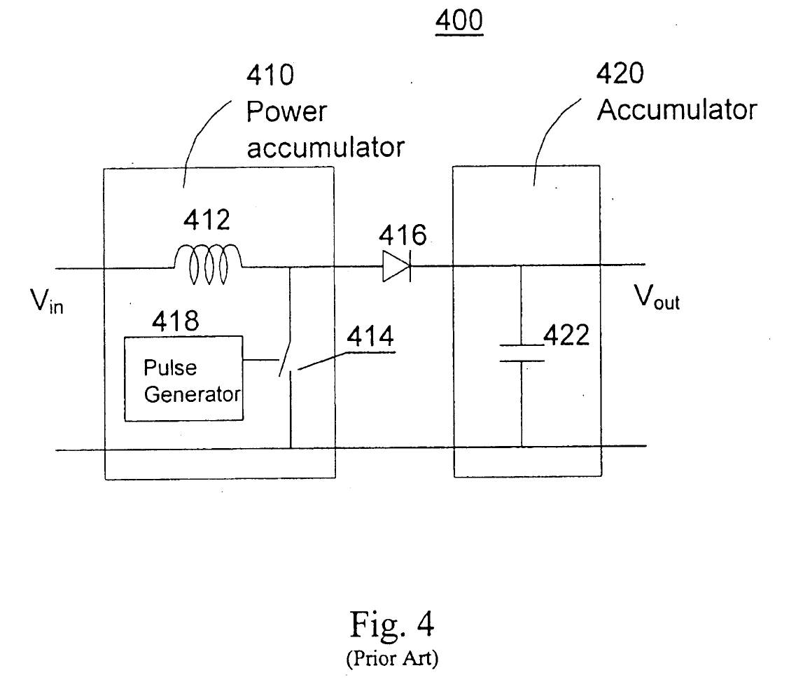

A conventional power extractor circuit 400 is shown in FIG. 4, which comprises a first power accumulator 410, a diode 416, and a second accumulator 420. The first power accumulator 410 comprises an inductor 412, a switch 414, and a pulse generator 418. The switch 414 is controlled by the pulse generator 418. The second accumulator 420 comprises a capacitor 422. If the switch 414 has been open for a relatively long time, the voltage across the capacitor 422 is equal to the input voltage. When the switch 414 closes (charge phase), the power is stored in the inductor 412 and the diode 416 prevents the capacitor 422 from being discharged. When the switch 414 opens (discharge phase), the charge stored in the inductor 412 is discharged to and accumulated in the capacitor 422. If the process of opening and closing the switch is repeated over and over, the voltage across the capacitor 422 will rise with each cycle.

Conventional DC-to-DC converters normally employ a feedback and control element to regulate the output voltage. However, the converter circuit 315 does not require a feedback and control element. In an embodiment of the invention, the converter circuit 315 comprises an inverted topology within the power extractor circuit 400 where the inductor 412 and the diode 416 are swapped. In another embodiment of the invention, the converter circuit 315 comprises a boost transformer flyback topology yielding a boosted, inverted and isolated output voltage.

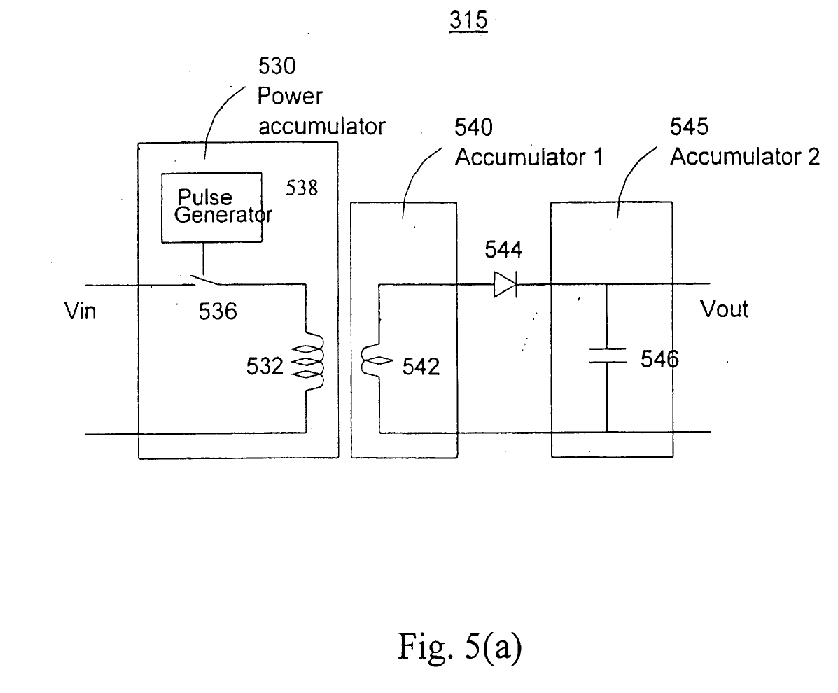

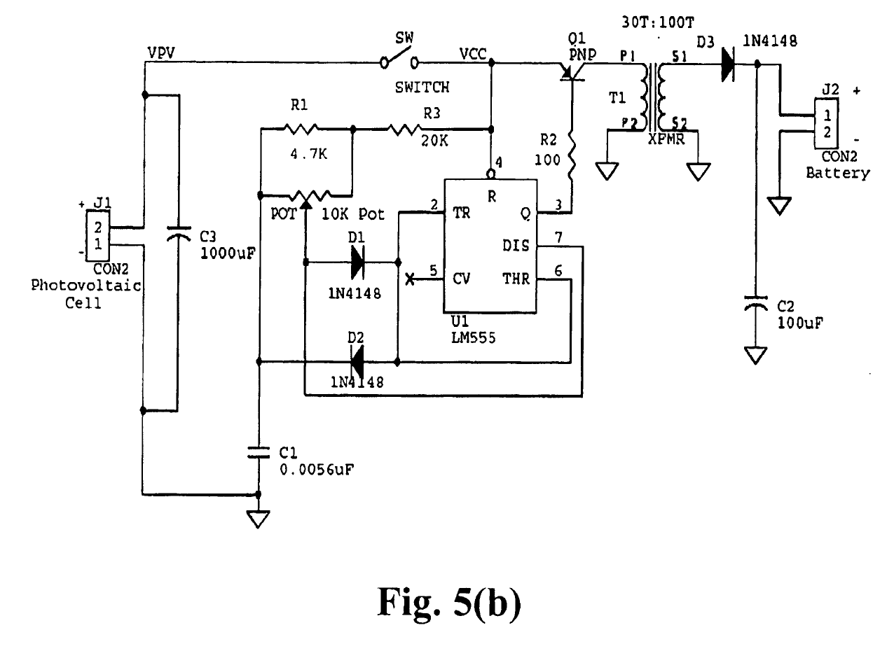

FIG. 5(a) illustrates a converter circuit 315 implementing a boost transformer flyback topology according to an embodiment of the invention. Particularly, the converter circuit 315 comprises a power accumulator 530, a first non-power accumulator 540, and a second non-power accumulator 545. The power accumulator 530 comprises a primary coil 532 of the transformer 534 and a switch 536 controlled by a pulse generator 538. The first non-power accumulator 540 comprises a secondary coil 542 of the transformer 534. The second non-power accumulator 545 comprises a capacitor 546. The diode 544 has the same function as described in FIG. 4 during the charge and discharge phases. In this transformer flyback topology, the primary coil of the transformer 532 is the inductor of the power accumulator 530. The capacitor 546 or the secondary coil of the transformer 542 each serve as accumulators. By using a high ratio of primary coil 532 to secondary coil 542 of the transformer, the converter circuit 315 boosts the current level supplied to the second 540 and third 545 accumulators, e.g., the secondary coil 542 or an extra capacitor 546 in parallel with the secondary coil 542. In an embodiment of the invention, the switch 536 in the power accumulator 530 comprises a transistor connected across the source and drain (or emitter/collector) with the gate (or base) controlled by the pulse signal generator 530.

FIG. 5(b) illustrates an exemplary circuitry implementation of converter circuit 315. Again, the circuit generates an output current from the power source using a switch mode power converter. The control loop is closed around the input voltage to the converter and not around the output voltage. The output voltage is allowed to float, being clamped by the loading conditions. If the outputs from multiple units are tied together, the currents will sum. If the output(s) are connected to a battery, the battery's potential will clamp the voltage during charge. This circuit methodology allows all cells that are producing power and connected in parallel to work at their peak efficiency.

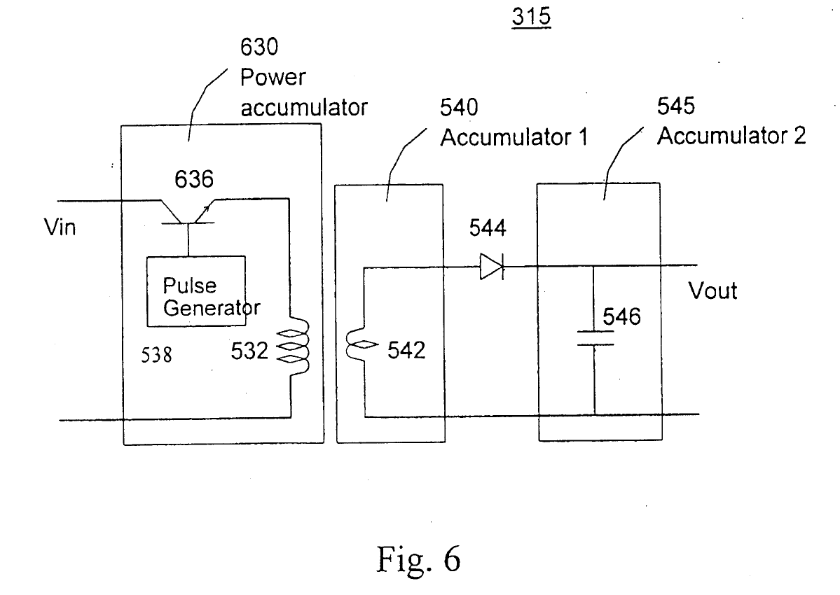

FIG. 6 illustrates the converter circuit 315 according to another embodiment of the invention. Here, the converter circuit 315 comprises a power accumulator 630, the first non-power accumulator 540, the second non-power accumulator 545, and the diode 544. The power accumulator 630 comprises the primary coil 532 of the transformer 534 and a transistor switch 636 controlled by the pulse generator 538. The power accumulator operates in conjunction with either the accumulator 540, which comprises the secondary coil 542 of the transformer 534 or the accumulator 545, which comprises the capacitor 546. Popular control techniques include pulse-frequency modulation, where the switch 636 is cycled at a 50% duty cycle; current-limited pulse-frequency modulation, where the charge cycle terminates when a predetermined peak inductor current is reached, and pulse-width modulation, where the switch frequency is constant and the duty cycle varies with the load.

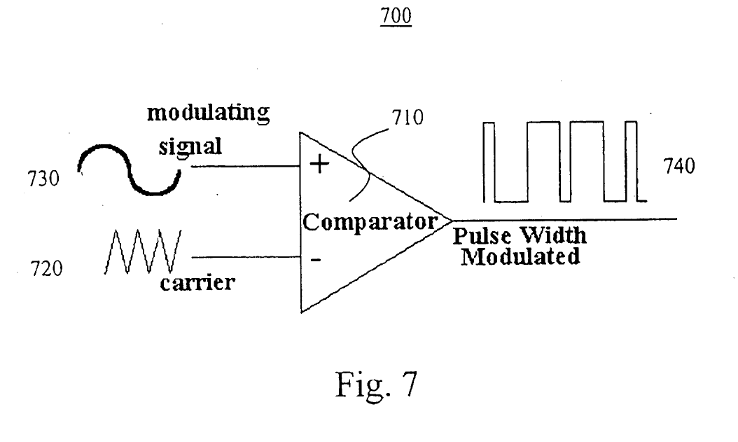

FIG. 7 illustrates a block diagram of a conventional pulse width modulation technique 700 employing a comparator 710 operating on a sawtooth carrier signal 720 and a sine modulating signal 730. The sawtooth carrier signal 720 and the sine modulating signal 730 are fed to the comparator 710 and the resulting output 740 is the pulse width modulated signal. The output signal of the comparator goes high when the sine wave signal is higher than the sawtooth signal.

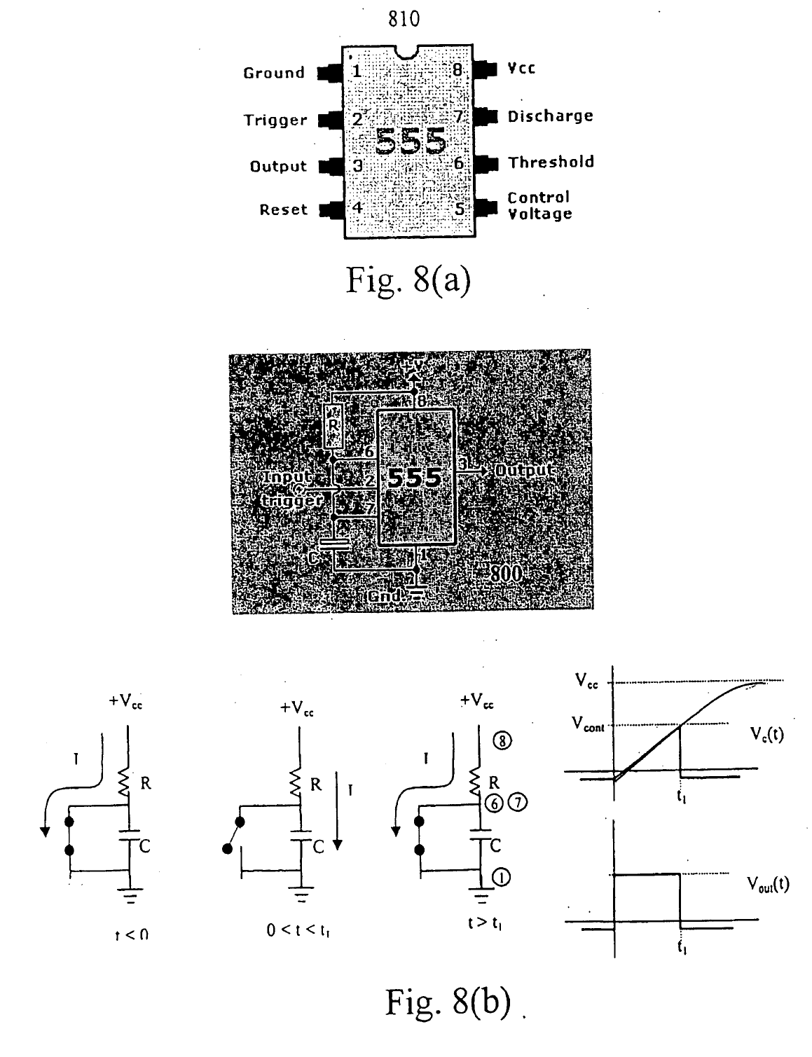

In an embodiment of the invention, the pulse generator 538 comprises a timing circuit 800 as illustrated in FIG. 8(a)-(b). The timing circuit 800 comprises a timer chip 810 such as, but not limited to a 555 timer chip, the implementation of which is apparent to one of ordinary skill in the art. The timing calculations for the 555 timer are based on the response of a series resister (R) and a capacitor (C) circuit (“R-C circuit”) with a step or constant voltage input and an exponential output taken across the capacitor. The two basic modes of operation of the 555 timer are: (1) monostable operation in which the timer wakes up generates a single pulse then goes back to sleep and (2) a stable operation, in which the timer is trapped in an endless cycle—generates a pulse, sleeps, generates a pulse, sleeps, . . . on and on forever.

Referring to the circuits shown in FIG. 8(b) which are schematics of a 555 timer chip with the resistor and capacitor in monostable (one-pulse) operation, which can be understood with varying input V_{trigger} and V_{cc} parameters and the resulting Vₒᵤₜₚᵤₜ for the following events in sequence. The lower case “t” designates time in these drawings. For the case where t<0, a closed switch keeps the capacitor uncharged with a resulting voltage on the capacitor of V_{c}=0 and output voltage Vₒᵤₜ of low value. For the case where t=0, a triggering event occurs and V_{tigger} very briefly drops below V_{control}/2 very. This causes the switch to open. For the case where (0<t<t₁), V_{c}(t) rises exponentially toward V_{cc} with time constant RC. Vₒᵤₜ is high for this case. For the case where (t=t₁), V_{c} reaches V_{control}. This causes the switch to close which instantly discharges the capacitor. For the case where (t>t₁) a closed switch keeps the capacitor uncharged and V_{c}=0 and Vₒᵤₜ of low value.

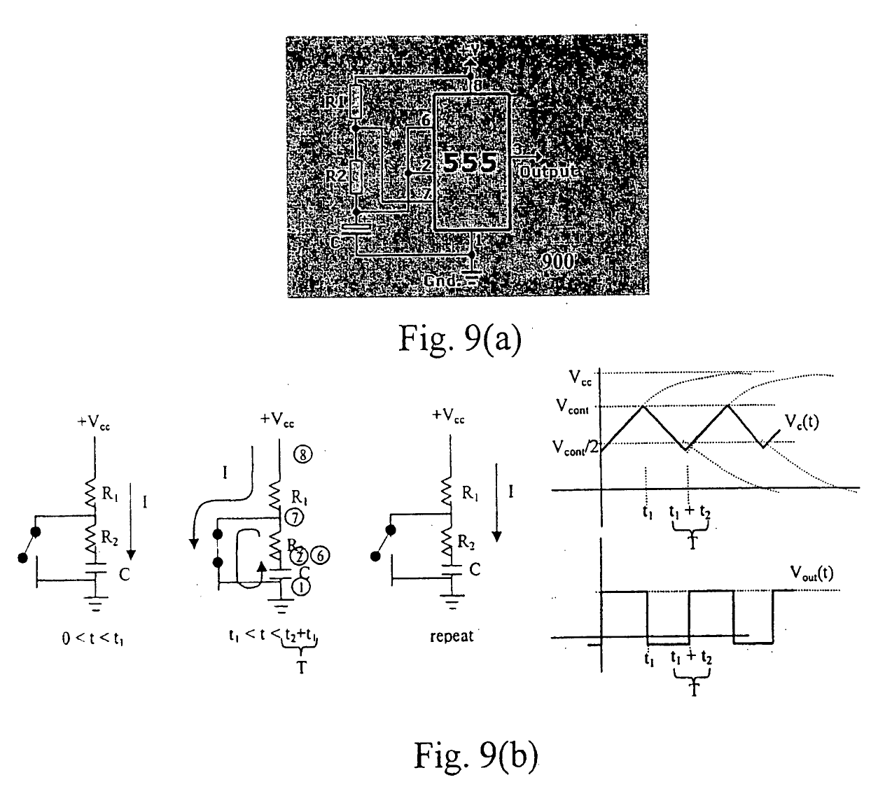

FIG. 9(a)-(b) illustrate the stable (pulse train) operation of timing circuit 900, which can be understood as consisting of the following events starting at a point where V_{c}=V_{control}/2. As shown in FIG. 9(b), in the case where t=0, V_{c}=V_{control}/2, and the switch opens. For the case where 0<t<t₁, V_{c}(t) rises exponentially toward V_{cc} with time constant (R₁+R₂)C. Vₒᵤₜ is of a high value. For the case where t=t₁, V_{c} reaches V_{control}. This causes the switch 860 to close. For the specific case where (t₁<t<t₁+t₂), V_{c}(t) falls exponentially toward zero with time constant R₂C. Vₒᵤₜ is at a low value. For the case where t=t₁+t₂=T, V_{c} reaches V_{control}/2. This causes the switch to open. These conditions are the same as in step 1, so the cycle repeats every T seconds.

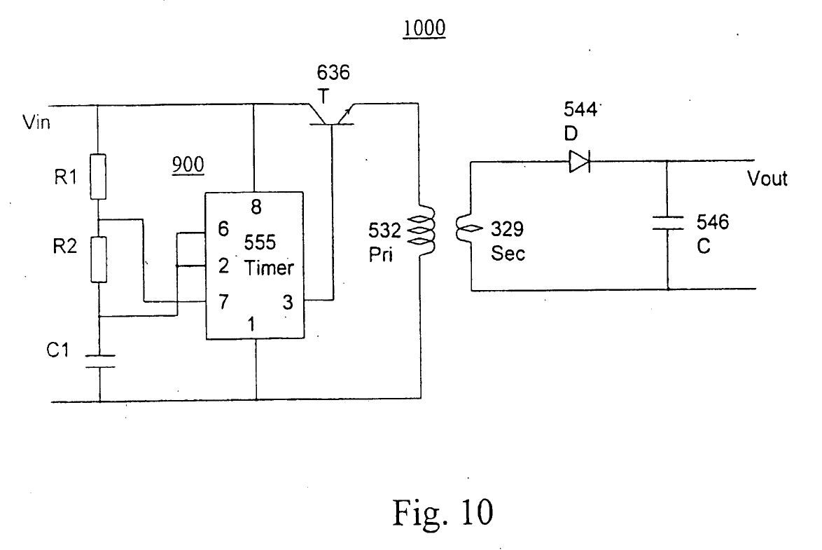

An efficiency booster circuit 1000 according to another embodiment of the present invention is shown in FIG. 10, which uses the 555 timer circuit 900 described in FIG. 9. The circuit 1000 uses a transformer flyback topology to isolate the output voltage. It can also provide higher current to charge the capacitor 1020. The 555 timer 900 is particular suitable for a selected 17 V solar cell array, since the voltage rating of the 555 timer 900 is between 4.5 V and 18 V. Thus this embodiment can be operated for incident solar radiation supplied from a solar cell array with a voltage down to 4.5 V, thereby providing power beyond the range of a standard solar panel.

For further operation down to output voltages of 0.3 V of the solar cell array, an oscillator that operates at lower voltage is included according to an embodiment of the invention. A ring oscillator that is limited in operation below 0.4 or 0.5 V (see U.S. Pat. No. 5,936,477 to Wattenhofer et al., the disclosure of which is herein incorporated by reference in its entirety) provides a voltage boost.

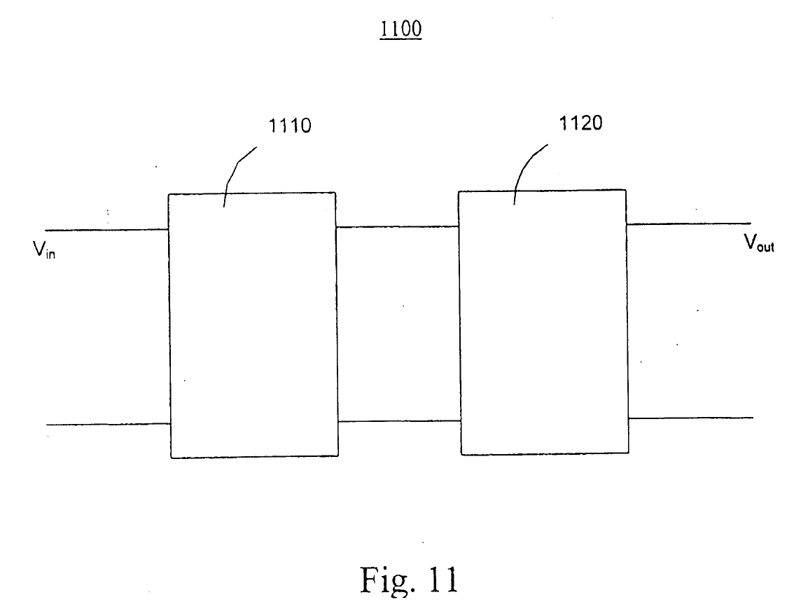

FIG. 11 illustrates a cascading system 1100 comprising multiple efficiency booster circuits according to an embodiment of the invention. Particularly, a first efficiency booster circuit 1110 and a second efficiency booster circuit 1120 are connected in series to cover the voltage range needed. Cascading and a circuit breaker might be further needed to ensure proper operation. Although only two efficiency booster circuits are shown, one of ordinary skill in the art recognizes that three or more efficiency booster circuits may be connected together in series.

In another embodiment of the invention, further components of a solar power can be included, for example a battery charger that uses a pulse-width-modulation (PWM) controller and a direct current (DC) load control and battery protection circuit and an inverter for generating AC voltages to operate conventional equipment, the implementation of all of which are apparent to one of ordinary skill in the art.

During use, the solar cell array can be spread open to increase their light receiving area for use in charging a battery pack, and it can be folded into a compact form to be stored when not in use. Since the solar cells are thin, the solar cell cube is relatively compact. The solar cells may be made larger by increasing the number of amorphous silicon solar cell units. A plurality of solar cells may also be connected electrically by cables or other connectors. In this fashion, solar cell output can easily be changed. Hence, even if the voltage or capacity requirement of a battery changes, the charging output can easily be revised to adapt to the new charging requirement. The charging technology of the present invention can also adjust the “Battery Charging Window” by utilizing techniques in power supply switching technology to move the charging window closer to the maximum efficiency point on the IV curve of the solar cell. The power generated is then used to either charge the reserve batteries or to offset the discharge time while the batteries are at full charge and under load.

The present invention is also particular suitable for low cost solar cells since these solar cells tend to produce less power and are not as efficient as the high cost ones. Flexible solar cell panels, as for example plastic panels, are low cost solar cells that can benefit from the present invention power extraction circuit.

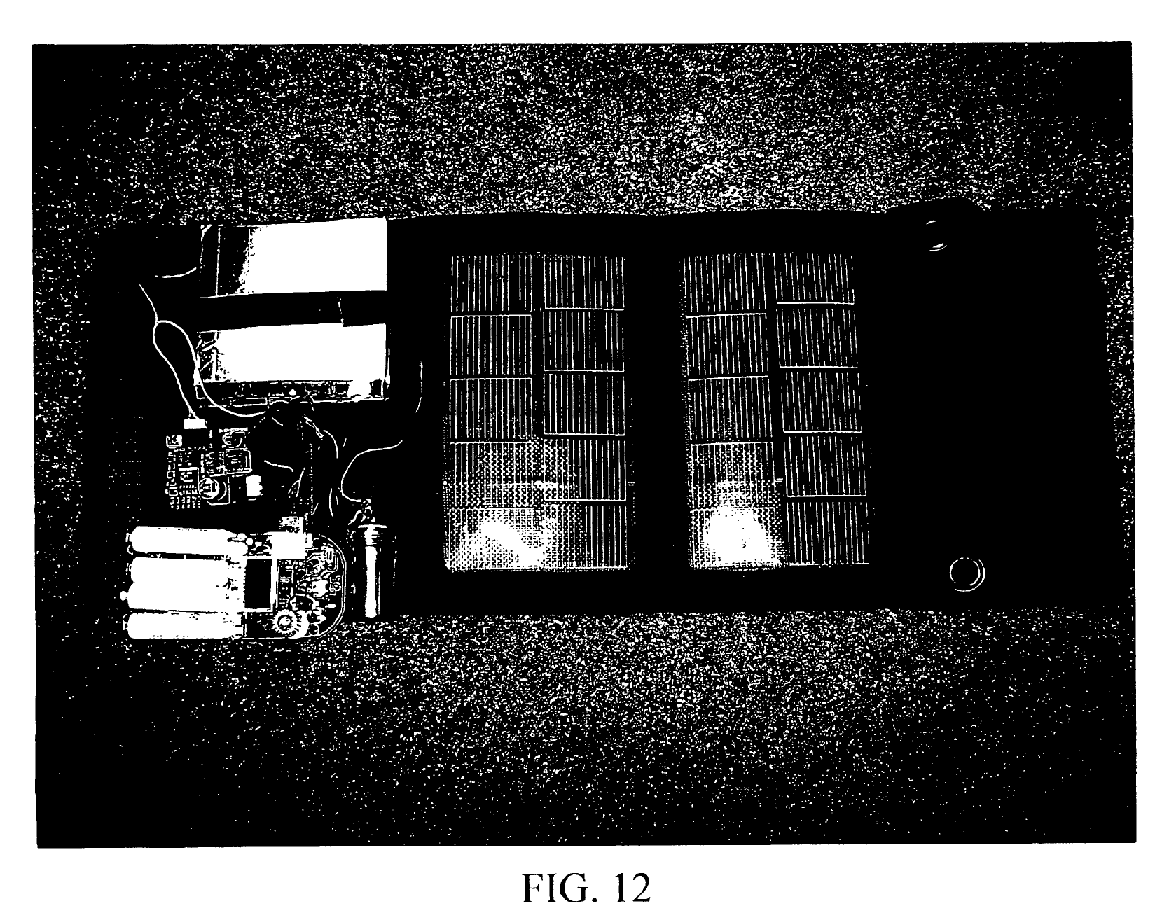

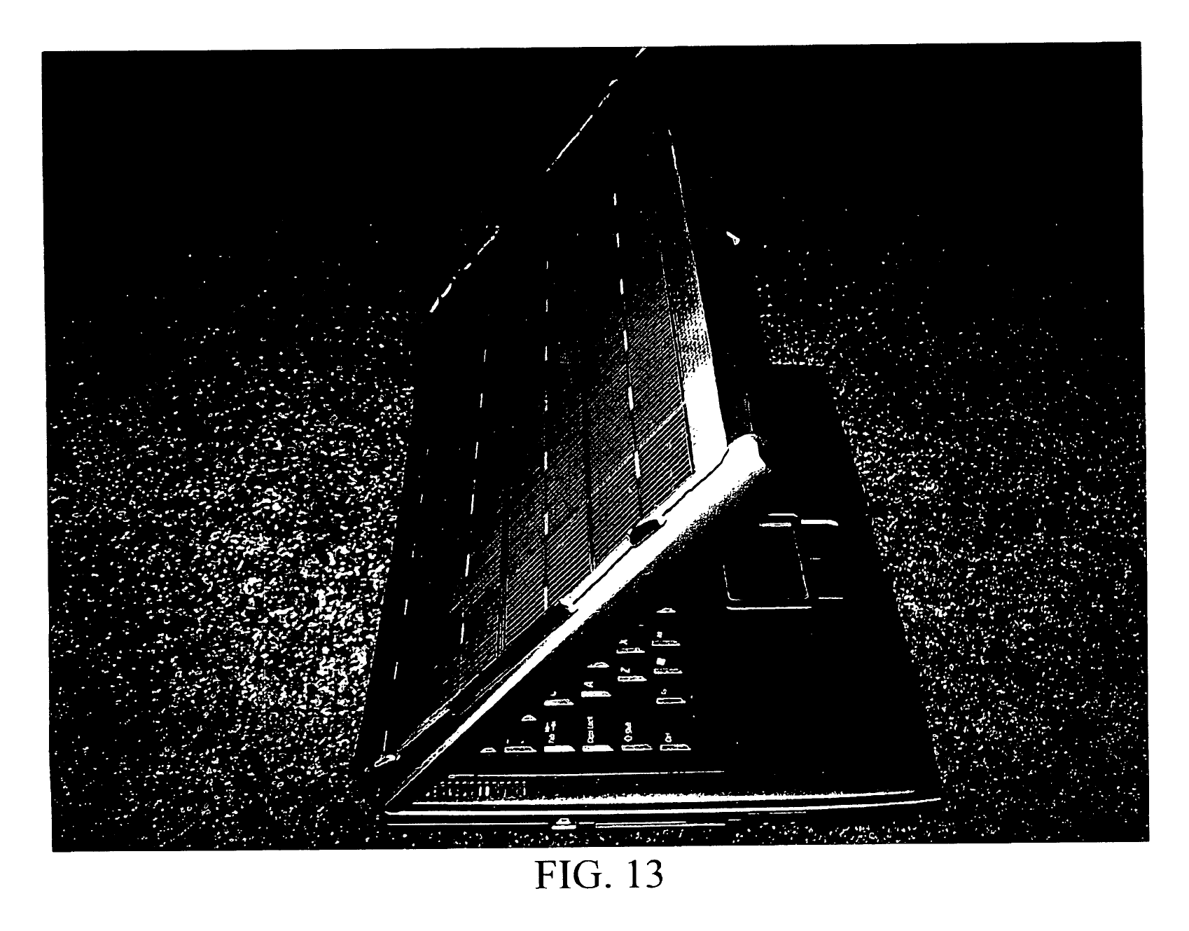

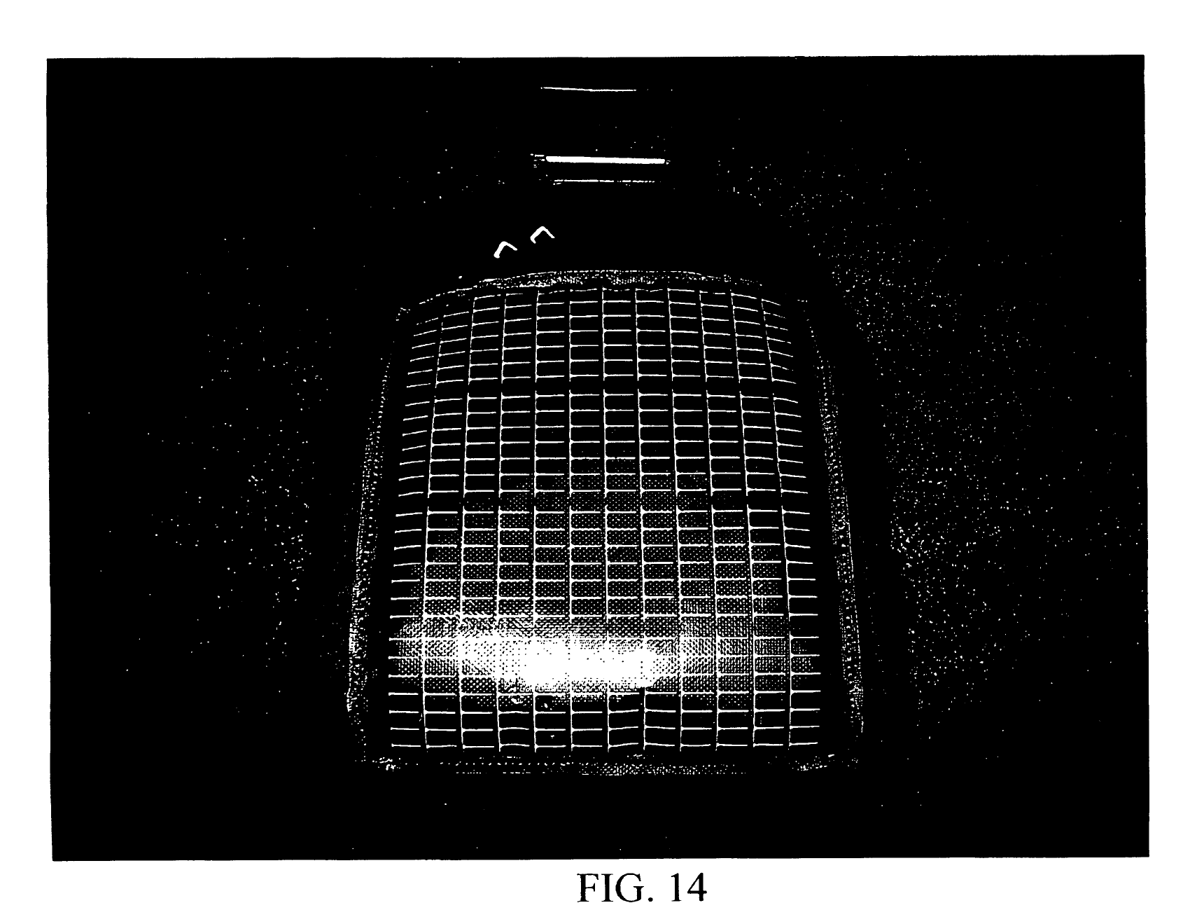

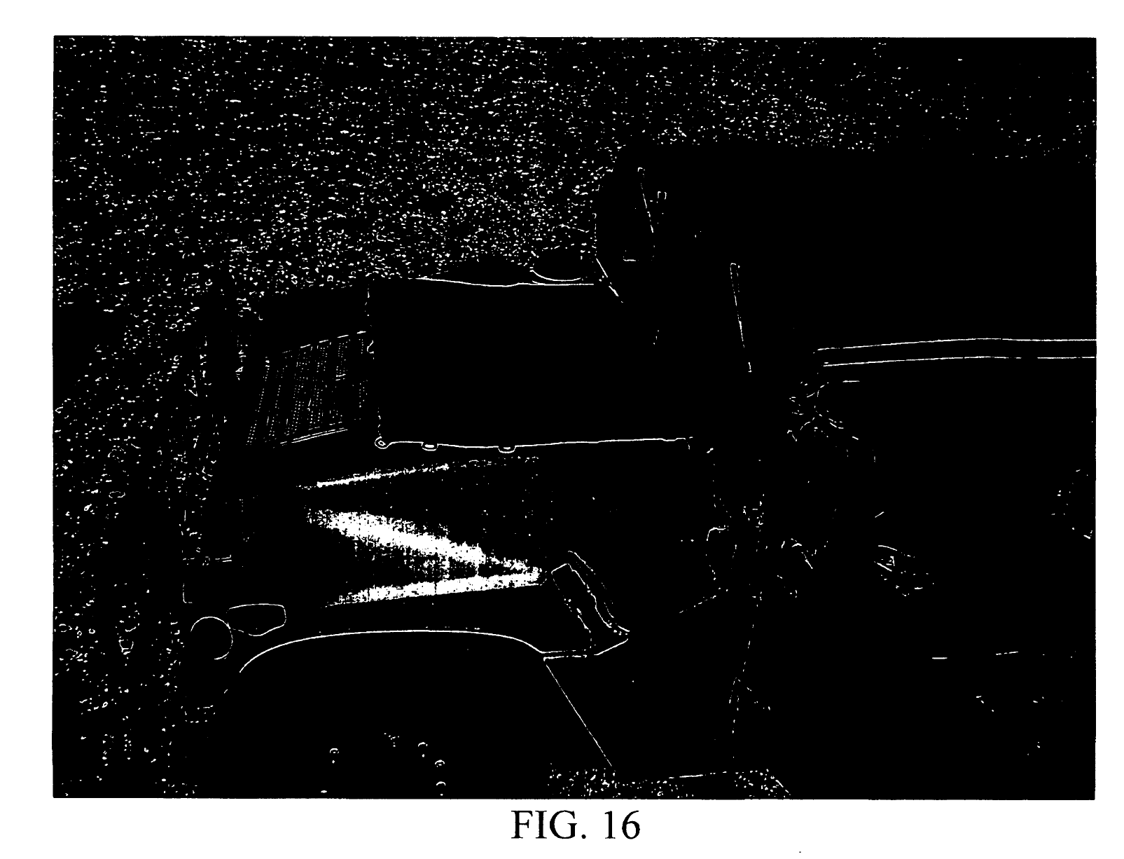

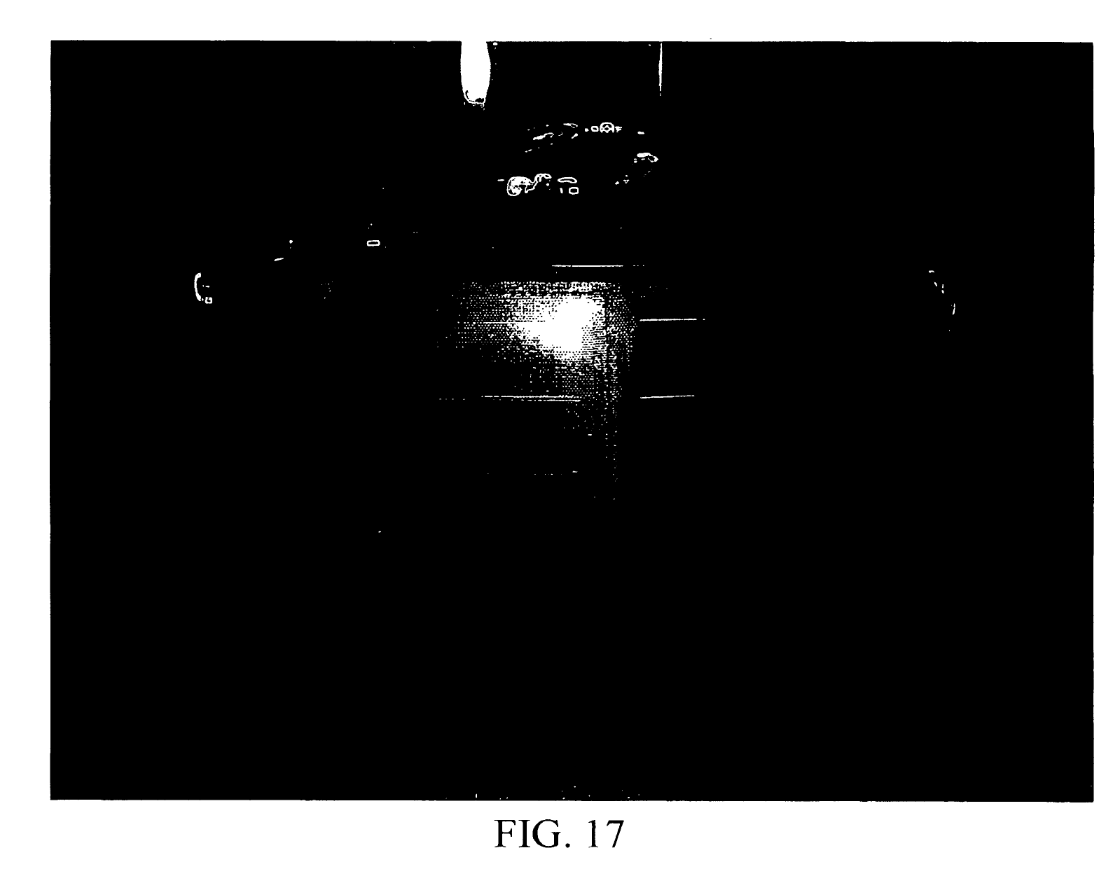

The following figures illustrate applications for which the present invention could be used. FIG. 12 shows a universal battery charger using the circuitry of the present invention. The charger employs a solar panel (not shown) connected to various charger configurations. FIG. 13 shows a laptop computer charger using the present invention. The solar panel is preferably a flexible panel attached to the lid of the computer. FIG. 14 shows a rolling backpack power generator and charger using the present invention. The solar panel is preferably a flexible panel attached to the side of the backpack. FIG. 16 shows a poncho power generator and charger using the present invention. The solar panel is preferably a flexible panel attached to the poncho. FIG. 17 shows a tent power generator and charger using the present invention. The solar panel is preferably a flexible panel attached to the tent. FIG. 18 shows a purse power generator and charger using the present invention. The solar panel is preferably a flexible panel attached to the purse. A cell phone charger can also implement the present invention. The solar panel is preferably a flexible panel attached to the lid of the cell phone (not shown).

The circuitry of the present invention can be tailored for each battery technology including nickel cadmium (Ni—CD) batteries, lithium ion batteries, lead acid batteries, among others. For example Ni—CD batteries need to be discharged before charging occurs.

The converter circuit of the present invention is designed to improve the output efficiency of a solar panel without requiring a costly MPPT circuit. Particularly, the converter circuit changes the output voltage or current of the solar panel before delivering it to a load or battery. In an embodiment of the invention, the converter circuit comprises a step-up DC to DC converter (called a booster circuit), a step-down DC to DC converter (called a buck circuit), or a combination thereof.

It will be apparent to those skilled in the art that various modifications and variation can be made in the present invention without departing from the spirit or scope of the invention. Thus, it is intended that the present invention covers the modifications and variations of this invention provided they come within the scope of the appended claims and their equivalence.

1. A system comprising:
a power source having a varying output voltage, and
a converter circuit electrically coupled to said power source, wherein said converter circuit regulates said varying output voltage to a constant voltage.

2. The system of claim 1, wherein said converter circuit dynamically modifies an electrical load based on the available power generated by said power source.

3. The system of claim 1, wherein said power source comprises one or more solar cells.

4. The system of claim 1, wherein said power source and said converter circuit are enclosed by a single housing.

5. The system of claim 1, further comprising a battery electrically coupled to said converter circuit.

6. The system of claim 5, wherein said converter circuit charges said battery when said varying output voltage of said power source is below a charging voltage of said battery.

7. The system of claim 1, wherein the converter circuit comprises a switch mode converter.

8. The system of claim 1, wherein the converter circuit comprises:
a primary coil of a transformer;
a secondary coil of a transformer;
a switch coupled to said primary coil;
a pulse generator coupled to said switch, wherein the pulse generator controls the switch;
a diode coupled to said secondary coil, and
a capacitor coupled to said diode.

9. The system of claim 8, wherein said pulse generator comprises a timer chip.

10. A universal battery charger comprising the system of claim 1.

11. A laptop computer comprising the system of claim 1.

12. A power generator comprising the system of claim 1.

13. A cell phone charger comprising the system of claim 1.

14. A tent power generator comprising the system of claim 1.
